(19) United States
(12) Patent Application Publication
(10) Pub. No.: US 2025/0187905 A1
(43) Pub. Date: Jun. 12, 2025

(54) MICRO-ELECTROMECHANICAL SYSTEM (MEMS) MIRROR COMB DRIVE

(71) Applicant: Lumentum Operations LLC, San Jose, CA (US)

(72) Inventors: Wenlin JIN, Ottawa (CA); Parsoua ABEDINI SOHI, Nepean (CA); Michael MILLER, Ottawa (CA); Gonzalo WILLS, Ottawa (CA)

(21) Appl. No.: 18/431,726

(22) Filed: Feb. 2, 2024

Related U.S. Application Data
(60) Provisional application No. 63/607,978, filed on Dec. 8, 2023.

(51) Int. Cl. B81B 3/00; B81C 1/00; G02B 26/08

(52) U.S. Cl. CPC B81B 3/007; B81C 1/00396; G02B 26/0841; B81B 2201/033; B81B 2201/045; B81B 2203/04; B81C 2201/013; B81C 2201/019

(57) ABSTRACT

In some implementations, a phase-shifting optical device includes a micro-electromechanical system (MEMS) device, comprising: a substrate; an electrode layer disposed on the substrate; a mirror layer disposed on the electrode layer, wherein the mirror layer is configured to cause a phase shift of an optical beam; a set of stator teeth formed from at least a first portion of the mirror layer and at least a portion of the electrode layer, and a set of rotor teeth formed from at least a second portion of the mirror layer and disposed on a hinge and engaged with the set of stator teeth.

### CROSS-REFERENCE TO RELATED APPLICATION

This patent application claims priority to U.S. Provisional Patent Application No. 63/607,978, filed on Dec. 8, 2023, and entitled “COMB DRIVE FOR MICRO-ELECTROMECHANICAL SYSTEM MIRRORS.” The disclosure of the prior application is considered part of and is incorporated by reference into this patent application.

### TECHNICAL FIELD

The present disclosure relates generally to a micro-electromechanical system (MEMS) device and to a MEMS mirror comb drive.

### BACKGROUND

A comb drive is a type of micro-electromechanical system (MEMS) actuator. A comb drive uses electrostatic forces acting between a pair of electrically conductive combs. For example, a voltage source may apply a voltage between a static comb and a moving comb to cause the moving comb to be displaced relative to the static comb. In optical systems, such as optical communications systems, optical sensing systems, or optical measurement systems, among other examples, a comb drive may be attached to an optical component to enable the optical component to be adjusted. For example, a comb drive may be attached to a mirror to change an orientation of the mirror as a response to an application of a voltage to the comb drive.

### SUMMARY

In some implementations, a micro-electromechanical system (MEMS) device includes a mirror layer, wherein the mirror layer is configured to cause a phase shift of an optical beam; a set of stator teeth formed from at least a first portion of the mirror layer; and a set of rotor teeth formed from at least a second portion of the mirror layer, wherein the set of rotor teeth is disposed on a hinge and engaged with the set of stator teeth.

In some implementations, a method for manufacturing a MEMS device includes disposing, by a manufacturing device, an electrode layer on a wafer layer; disposing, by the manufacturing device, a mirror layer on the wafer; etching, by the manufacturing device, the mirror layer to form an offset between a first surface of the mirror layer and a second surface of the mirror layer; and etching, by the manufacturing device, the mirror layer to form a set of rotors and a set of stators, wherein the set of rotors include at least a portion of the first surface of the mirror layer and the set of stators include at least a portion of the second surface of the mirror layer.

In some implementations, a phase-shifting optical device includes a MEMS device, comprising: a substrate; an electrode layer disposed on the substrate; a mirror layer disposed on the electrode layer, wherein the mirror layer is configured to cause a phase shift of an optical beam; a set of stator teeth formed from at least a first portion of the mirror layer and at least a portion of the electrode layer; and a set of rotor teeth formed from at least a second portion of the mirror layer and disposed on a hinge and engaged with the set of stator teeth.

### BRIEF DESCRIPTION OF THE DRAWINGS

FIGS. 1A-1B are diagrams of an example implementation associated with a MEMS mirror comb drive.

FIGS. 2 and 3A-3E are diagrams of an example associated with manufacturing a MEMS comb drive.

### DETAILED DESCRIPTION

The following detailed description of example implementations refers to the accompanying drawings. The same reference numbers in different drawings may identify the same or similar elements.

Micro-electromechanical systems (MEMS) devices may be used as control elements, such as actuators, in optical systems, such as optical communications systems, optical measurement systems, or optical sensing systems, among other examples. For example, a MEMS mirror with one degree of linear motion may be used for phase shifting of optical beams in an optical system. By phase shifting one or more optical beams using a MEMS mirror, the MEMS mirror may enable constructive combining of a set of optical beams, thereby enabling an optical system to output a single beam with a greater power level than each individual optical beam of the set of optical beams. In such use cases, relatively small movements in the MEMS mirror, which may result from poor positional stability of the MEMS mirror, can cause the set of beams to be out of phase, which may prevent efficient optical combining.

When a parallel plate MEMS actuator is used, an effective stiffness factor (e.g., which may correspond to a level of mechanical stability) decreases as an actuation range increases relative to a gap between parallel plates. In other words, when the parallel plate MEMS actuator is actuated toward a maximum position, the parallel plate MEMS actuator may experience reduced mechanical stability, which may result in poor phase stability and inefficient combining. Additionally, or alternatively, at relatively large displacements between parallel plates of the parallel plate MEMS actuator, the parallel plate MEMS actuator may be susceptible to damage from vibrations or inadvertent contact. Accordingly, to maintain mechanical stability and/or avoid a risk of breakage, the parallel plate MEMS actuator may be configured with a gap between parallel plates that is large relative to a moving range of the parallel plate MEMS actuator. However, having a large gap between the parallel plates may result in poor heat conductance and dissipation, which may result in aberrations or poor performance when combining.

A comb drive MEMS actuator may have stator teeth and rotor teeth forming parallel plates in different layers, with a gap between the rotor teeth and the stator teeth staying constant during operation. Accordingly, a comb drive MEMS actuator may maintain a constant effective stiffness factor. However, an overlap area between the rotor teeth and the stator teeth is relatively small in an initial engagement state of the comb drive MEMS actuator. Accordingly, the relatively small overlap area may result in poor heat conductance and dissipation, which may result in aberrations to combining.

Some aspects described herein may provide a comb drive MEMS device with a relatively high heat conductance and heat dissipation level as well as a relatively high effective stiffness factor. In such aspects, the comb drive MEMS device may include a set of rotor teeth and a set of stator teeth that are formed from a common mirror layer, which may enable the comb drive MEMS device to be manufactured with a relatively small initial gap (e.g., relative to a size of the rotor teeth and stator teeth) and a relatively large overlap area (e.g., at least a threshold percentage of a rotor tooth overlaps with a stator tooth). In such aspects, the use of a comb drive configuration for a MEMS device can achieve a high, constant effective stiffness factor, which results in a high level of mechanical stability and resistance to breakage. Additionally, or alternatively, based on the set of rotor teeth and the set of stator teeth being formed from a common mirror layer, the MEMS device can achieve a relatively small initial gap and a relatively large overlap area, which can result in a relatively high level of heat conductance and heat dissipation. Accordingly, the MEMS device may achieve stable phase shifting for high-power optical systems.

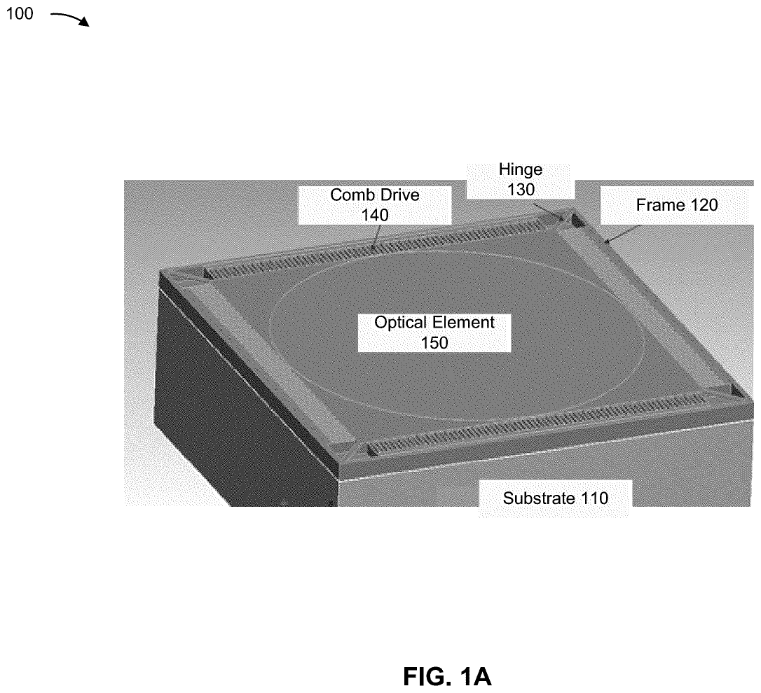

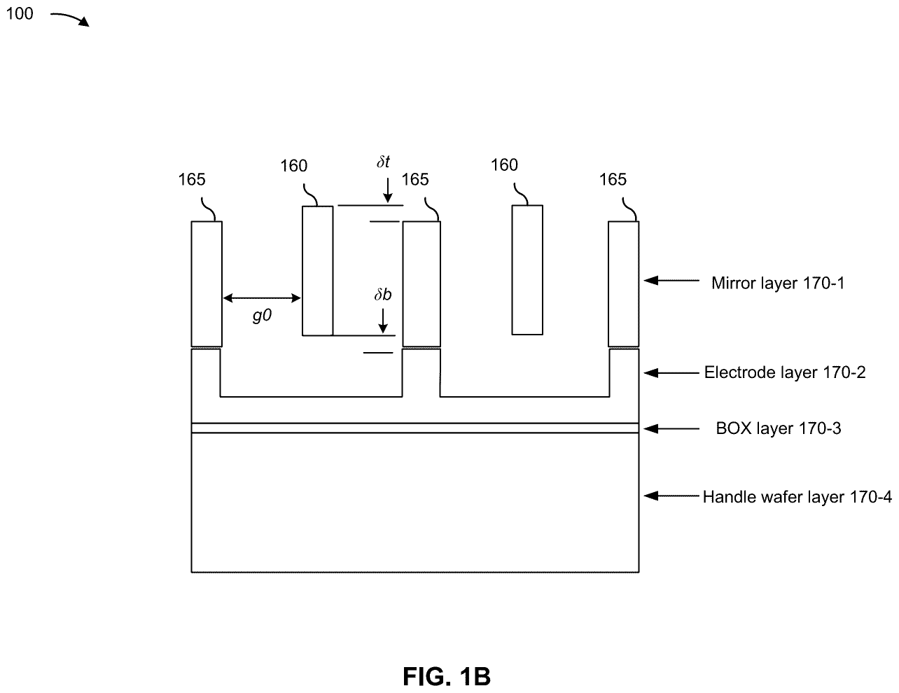

FIGS. 1A-1B are diagrams of an example optical device 100 associated with a MEMS mirror comb drive. As shown in FIG. 1A, example optical device 100 includes a substrate 110, a frame 120, a hinge 130, a comb drive 140, and an optical element 150.

The substrate 110 may include one or more layers of material to which the frame 120, hinge 130, and comb drive 140 are attached. For example, the substrate 110 may include a substrate layer, which is disposed below the optical element 150 and which is formed from a silicon handle wafer. The frame 120 and the hinge 130 may include a structure that supports the optical element 150. For example, the frame 120 and/or the hinge 130 may include a silicon structure that supports the optical element 150. The optical element 150 may include one or more optical components, such as a mirror, a lens, a grating, or another type of optical component.

The comb drive 140 may include one or more layers of material configured to actuate the optical element 150. As shown in FIG. 1B, the comb drive 140 may include a set of rotor teeth 160 that, when displaced relative to a set of stator teeth 165, cause the optical element 150 to be moved. For example, the frame 120 is fixed to the substrate 110 with the stator teeth 165. The hinge 130 connects to the frame 120 and the rotor teeth 160. The rotor teeth 160 are attached to the optical element 150. Accordingly, when the rotor teeth 160 are displaced relative to the stator teeth 165, the rotor teeth move (along with the hinge 130) and cause the optical element 150 to be displaced. In other words, a voltage applied to the comb drive 140 causes the rotor teeth 160 of the comb drive 140 to move, which may result in the optical element 150 being moved linearly (e.g., a translational movement). In some implementations, an optical element 150 may be tilted to a configured tilt angle.

The set of rotor teeth 160 is engaged with the set of stator teeth 165, such that a rotor tooth 160 is separated from a stator tooth 165 by a fixed gap g0. Each rotor tooth 160 may be disposed at an initial position, such that a top of a rotor tooth 160 is offset from a top of a stator tooth 165 by a top offset amount δt. Similarly, a bottom of a rotor tooth 160 is offset from a bottom of a stator tooth 165 by a bottom offset amount δb. In an example, when a length of the rotor teeth 160 and a length of the stator teeth 165 are the same length, the top offset amount and the bottom offset amount may be the same amount. In another example, when the rotor teeth 160 are associated with a first length and the stator teeth 165 are associated with a second length, the top offset amount may be different from the bottom offset amount. In some implementations, the top offset amount and the bottom offset amount may be greater than or equal to a movement range of the comb drive 140. For example, the optical device 100 may be configured such that the optical element 150 is associated with a particular phase shift range corresponding to a particular movement range. In this case, a translational movement range of the comb drive 140 and an associated size of a translational offset (e.g., the top offset amount and the bottom offset amount) may be selected to achieve the particular movement range of the optical element 150 and the corresponding particular phase shift range.

In some implementations, the optical device 100 may include a set of inputs and/or a set of outputs. For example, the optical device 100 may include an input to receive an input optical beam and an output to provide an output optical beam. In this case, when the optical device 100 includes a phase shift optical device, the optical device 100 may use the optical element 150 (e.g., a mirror) to apply a phase shift to the input optical beam to transform the input optical beam into the output optical beam. In other words, the output optical beam is phase-shifted with respect to the input optical beam. In another example, the optical device may perform a different optical function on the input beam to transform the input beam to the output beam, such as a frequency shifting function, a band blocking function, a combining function, or a splitting function (e.g., using one or more different optical elements 150 being controlled by the comb drive 140).

In some implementations, the comb drive 140 is formed from a set of layers 170. For example, the comb drive 140 may include a mirror layer 170-1, an electrode layer 170-2, a buried oxide (BOX) layer 170-3, and/or a handle wafer layer 170-4. In this case, one or more of the layers 170 may correspond to other elements of the optical device 100. In other words, in cross-section, as shown, one or more layers 170 of the comb drive 140 may correspond to components of the optical device 100. For example, the mirror layer 170-1 may correspond to the optical element 150 (e.g., a mirror). In other words, the set of rotor teeth 160 and the set of stator teeth 165 may be formed from the same layer that forms the optical element 150. Additionally, or alternatively, the electrode layer 170-2 and the BOX layer 170-3 may correspond to the frame 120 and/or the hinge 130. Additionally, or alternatively, the handle wafer layer 170-4 may correspond to the frame 120.

As indicated above, FIGS. 1A-1B are provided as an example. Other examples may differ from what is described with regard to FIGS. 1A-1B.

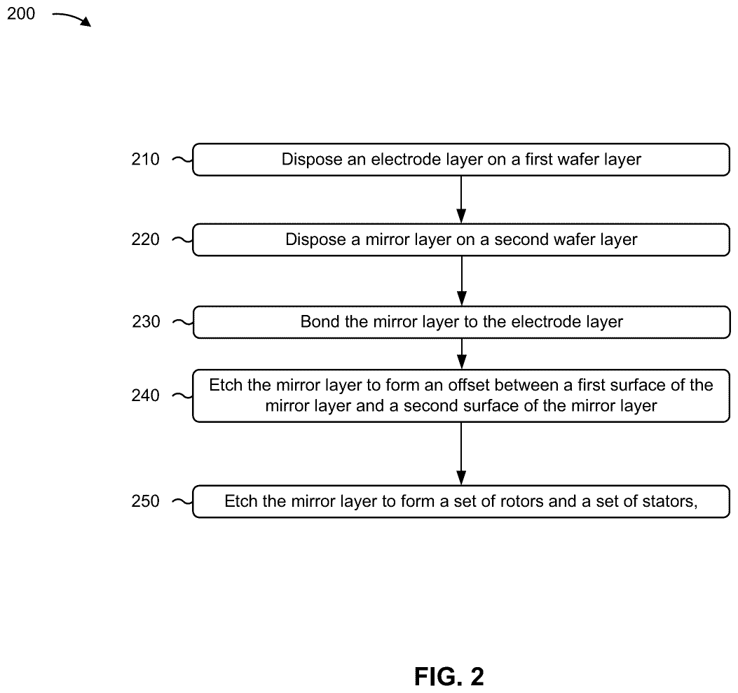

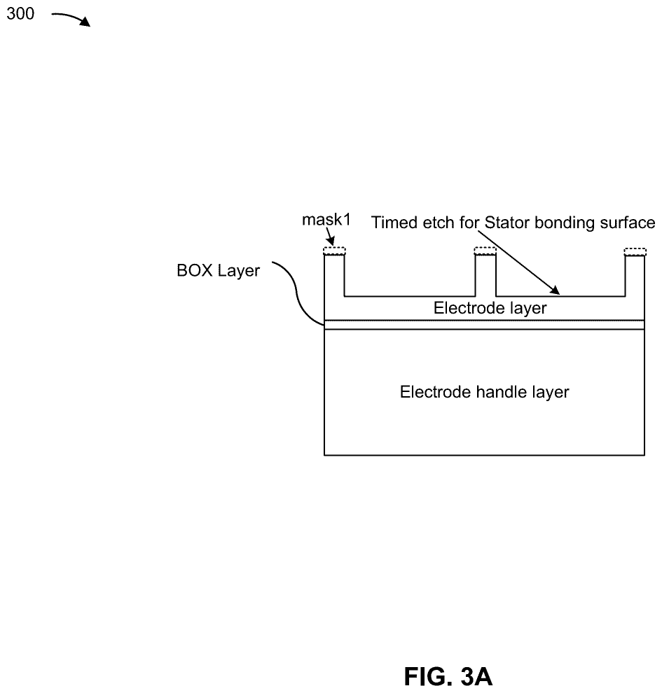

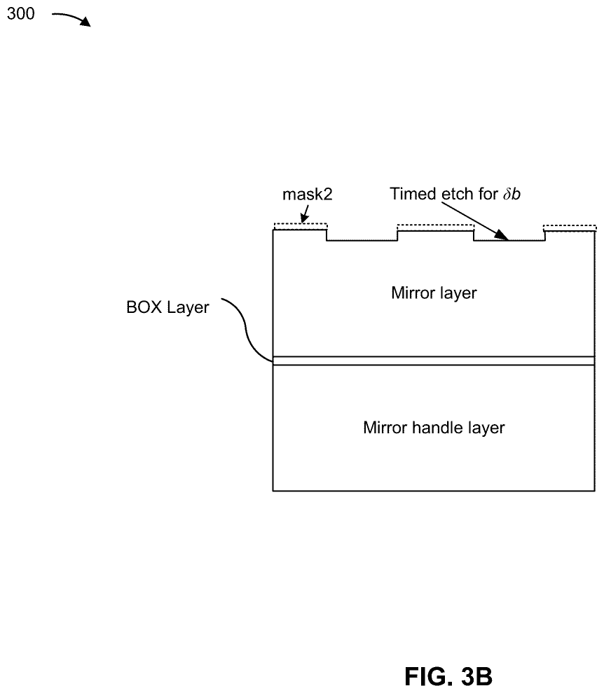

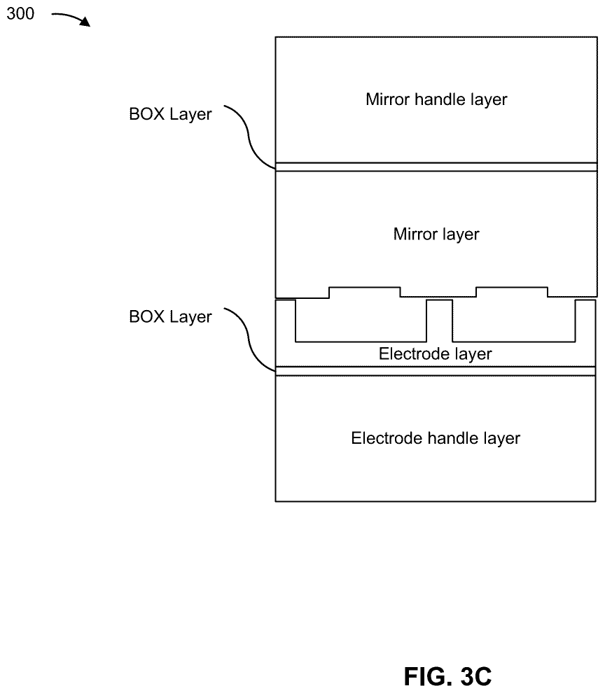

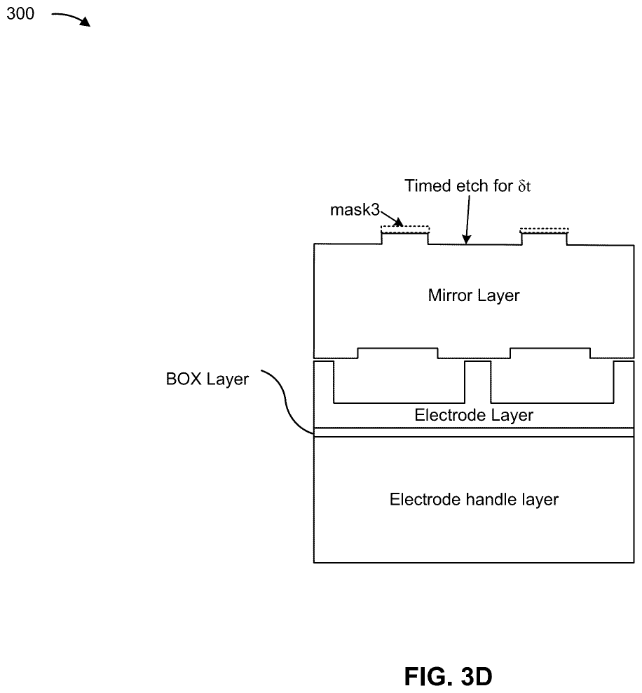

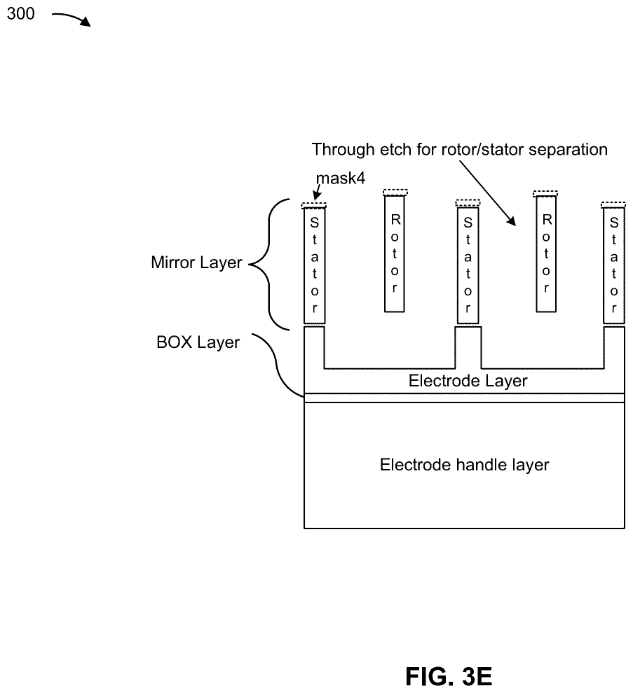

FIGS. 2 and 3A-3E are diagrams of an example 200/300 associated with manufacturing a MEMS comb drive. In some implementations, one or more steps of FIG. 2 are performed by a manufacturing device, such as an etching device, a masking device, or another type of device.

As shown in FIG. 2, example 200 may include disposing an electrode layer on a wafer layer (block 210). For example, the manufacturing device may dispose an electrode layer on a first wafer layer, as described above. As shown in FIG. 3A, the electrode layer may be disposed on an electrode handle layer. In some implementations, an intermediate layer may be disposed between the electrode layer and the electrode handle layer. For example, a buried oxide (BOX) layer may be disposed between the electrode handle layer and the electrode layer. In some implementations, the buried oxide layer may form an insulator layer between the electrode layer and the electrode handle layer. In some implementations, a masking and etching procedure may be applied to the electrode layer. For example, as shown in FIG. 3A, a first mask (e.g., “mask1”) is applied to a portion of a top surface of the electrode layer. In this case, the electrode layer is etched for a particular time period to form a stator bonding surface for the electrode layer, as described in more detail herein.

As further shown in FIG. 2, example 200 may include disposing a mirror layer on a wafer (block 220). For example, the manufacturing device may dispose a mirror layer on a wafer, as described above. As shown in FIG. 3B, the mirror layer may be disposed on a mirror handle layer (or mirror substrate). In some implementations, an intermediate layer may be disposed between the mirror layer and the mirror handle layer. For example, a buried oxide layer may be disposed between the mirror handle layer and the mirror layer. The buried oxide layer may include a silicon dioxide layer or another type of oxide layer. In some implementations, the buried oxide layer may form an insulator layer between the mirror layer and the mirror handle layer. In some implementations, a masking and etching procedure may be applied to the mirror layer. For example, as shown in FIG. 3B, a first mask (e.g., “mask2”) is applied to a portion of a top surface of the mirror layer. In this case, the mirror layer is etched for a particular time period to form a bottom offset amount δb for the mirror layer, as described in more detail herein.

As further shown in FIG. 2, example 200 may include bonding the mirror layer to the electrode layer (block 230). For example, the manufacturing device may bond the mirror layer to the electrode layer, as described above. As shown in FIG. 3C, the mirror layer is aligned to the electrode layer. In this case, the mirror layer is flipped, relative to an orientation in FIG. 3A, such that a top surface of the mirror layer in FIG. 3A is a bottom surface of the mirror layer in FIG. 3C (e.g., and is disposed onto a top surface of the electrode layer). In some implementations, based on aligning the mirror layer to the electrode layer, the mirror handle layer is removed from the mirror layer. For example, the mirror handle layer provides a surface for manipulating and positioning the mirror layer onto the electrode layer. Based on the mirror layer being disposed onto the electrode layer, the mirror handle layer may be removed to expose the mirror layer (e.g., to enable processing of a surface of the mirror layer). In this case, the buried oxide layer that was disposed between the mirror handle layer and the mirror layer may also be removed to expose a surface of the mirror layer for masking and etching.

As further shown in FIG. 2, example 200 may include etching the mirror layer to form an offset between a first surface of the mirror layer and a second surface of the mirror layer (block 240). For example, the manufacturing device may etch the mirror layer to form an offset between a first surface of the mirror layer and a second surface of the mirror layer, as described above. As shown in FIG. 3D, a third mask (e.g., “mask3”) is applied to a portion of a surface of the mirror layer and the mirror layer is etched to form a top offset amount δt. In this case, a top surface of the mirror layer (e.g., with respect to the orientation shown in FIG. 3D) is processed to have the top offset amount, such that a first portion of the top surface is at a first height above the electrode handle layer and a second portion of the top surface is at a second height above the electrode handle layer.

As further shown in FIG. 2, example 200 may include etching the mirror layer to form a set of rotors and a set of stators (block 250). For example, the manufacturing device may etch the mirror layer to form a set of rotors and a set of stators, as described above. As shown in FIG. 3E, a fourth mask (e.g., “mask4”) is applied to a portion of a surface of the mirror layer and the mirror layer is etched to form the set of rotors and the set of stators. In some implementations, the set of rotors include at least a portion of the first surface of the mirror layer and the set of stators include at least a portion of the second surface of the mirror layer. For example, the etching associated with the fourth mask is a through etch that extends through the mirror layer to form rotors and stators that are engaged with each other and not touching each other. In contrast, etching associated with the other masks may be a shallow etch (e.g., to form a size of a translational offset or a size of a gap between the stator teeth and the rotor teeth).

As shown in FIG. 3E, the stator teeth are attached to the electrode layer and the rotor teeth are suspended above the electrode layer. In this case, the rotor teeth are attached to a set of hinges (e.g., the hinge 130, as shown in FIG. 1A). The electrode layer may be connected to a controller (not shown), in some implementations. For example, a controller may cause a voltage to be provided via the electrode layer to the stator teeth, which may cause actuation. In this case, the rotor teeth may be caused to move relative to the stator teeth, thereby displacing a mirror attached to the rotor teeth and/or a set of hinges attached to the set of rotor teeth. In other words, a manufacturing device may form a set of hinges to suspend the set of rotor teeth above the electrode layer and in a position where the set of rotor teeth are engaged with the set of stator teeth.

In some implementations, a mask (e.g., the first, second, third, or fourth masks) may be associated with a size that is less than a threshold size. For example, the manufacturing device may apply a mask with a size (e.g., a width) of less than 1 micrometer (μm). Additionally, or alternatively, the manufacturing device may etch a layer (and mask) for a particular period of time. For example, the manufacturing device may etch for less than a threshold time, which may enable production of an offset value, for example, offsets δb and/or δt, of less than the threshold size. Similarly, by configuring a particular etch time or other parameter, the comb drive may have a gap g0 of less than a threshold gap size. Further, by using an etching procedure, the threshold size can be achieved with relatively small alignment errors. Having a relatively small gap between the rotors and the stators, with a relatively small level of alignment error, enables a high level of driving efficiency, a high level of mechanical stability (e.g., a stiffness factor that is greater than a threshold amount), and a high level of thermal conductivity and thermal dissipation capacity for the comb drive.

Example 200/300 may include additional implementations, such as any single implementation or any combination of implementations described herein.

Although FIGS. 2 and 3A-3E shows example steps of example 200/300, in some implementations, example 200/300 includes additional steps, fewer steps, different steps, or differently arranged steps than those depicted in FIGS. 2 and 3A-3E. Additionally, or alternatively, two or more of the steps of examples 200/300 may be performed in parallel.

The foregoing disclosure provides illustration and description, but is not intended to be exhaustive or to limit the implementations to the precise forms disclosed. Modifications and variations may be made in light of the above disclosure or may be acquired from practice of the implementations. Furthermore, any of the implementations described herein may be combined unless the foregoing disclosure expressly provides a reason that one or more implementations may not be combined.

As used herein, satisfying a threshold may, depending on the context, refer to a value being greater than the threshold, greater than or equal to the threshold, less than the threshold, less than or equal to the threshold, equal to the threshold, not equal to the threshold, or the like.

Even though particular combinations of features are recited in the claims and/or disclosed in the specification, these combinations are not intended to limit the disclosure of various implementations. In fact, many of these features may be combined in ways not specifically recited in the claims and/or disclosed in the specification. Although each dependent claim listed below may directly depend on only one claim, the disclosure of various implementations includes each dependent claim in combination with every other claim in the claim set. As used herein, a phrase referring to “at least one of” a list of items refers to any combination of those items, including single members. As an example, “at least one of: a, b, or c” is intended to cover a, b, c, a-b, a-c, b-c, and a-b-c, as well as any combination with multiple of the same item.

When a component or one or more components (e.g., a manufacturing device or one or more manufacturing devices) is described or claimed (within a single claim or across multiple claims) as performing multiple operations or being configured to perform multiple operations, this language is intended to broadly cover a variety of architectures and environments. For example, unless explicitly claimed otherwise (e.g., via the use of “first component” and “second component” or other language that differentiates components in the claims), this language is intended to cover a single component performing or being configured to perform all of the operations, a group of components collectively performing or being configured to perform all of the operations, a first component performing or being configured to perform a first operation and a second component performing or being configured to perform a second operation, or any combination of components performing or being configured to perform the operations. For example, when a claim has the form “one or more components configured to: perform X; perform Y; and perform Z,” that claim should be interpreted to mean “one or more components configured to perform X; one or more (possibly different) components configured to perform Y; and one or more (also possibly different) components configured to perform Z.”

No element, act, or instruction used herein should be construed as critical or essential unless explicitly described as such. Also, as used herein, the articles “a” and “an” are intended to include one or more items, and may be used interchangeably with “one or more.” Further, as used herein, the article “the” is intended to include one or more items referenced in connection with the article “the” and may be used interchangeably with “the one or more.” Furthermore, as used herein, the term “set” is intended to include one or more items (e.g., related items, unrelated items, or a combination of related and unrelated items), and may be used interchangeably with “one or more.” Where only one item is intended, the phrase “only one” or similar language is used. Also, as used herein, the terms “has,” “have,” “having,” or the like are intended to be open-ended terms. Further, the phrase “based on” is intended to mean “based, at least in part, on” unless explicitly stated otherwise. Also, as used herein, the term “or” is intended to be inclusive when used in a series and may be used interchangeably with “and/or,” unless explicitly stated otherwise (e.g., if used in combination with “either” or “only one of”). Further, spatially relative terms, such as “below,” “lower,” “above,” “upper,” and the like, may be used herein for ease of description to describe one element or feature's relationship to another element(s) or feature(s) as illustrated in the figures. The spatially relative terms are intended to encompass different orientations of the apparatus, device, and/or element in use or operation in addition to the orientation depicted in the figures. The apparatus may be otherwise oriented (rotated 90 degrees or at other orientations) and the spatially relative descriptors used herein may likewise be interpreted accordingly.

What is claimed is:

1. A micro-electromechanical system (MEMS) device, comprising:
a mirror layer,
wherein the mirror layer is configured to cause a phase shift of an optical beam;
a set of stator teeth formed from at least a first portion of the mirror layer; and
a set of rotor teeth formed from at least a second portion of the mirror layer,
wherein the set of rotor teeth is disposed on a hinge and engaged with the set of stator teeth.

2. The MEMS device of claim 1, wherein the mirror layer is a silicon on insulator (SOI) layer.

3. The MEMS device of claim 1, wherein the set of stator teeth and the set of rotor teeth form an actuator.

4. The MEMS device of claim 1, wherein a stator tooth, of the set of stator teeth, is engaged with a rotor tooth, of the set of rotor teeth, and
wherein the stator tooth is offset from the rotor tooth by an amount that is greater than or equal to a moving range of the MEMS device.

5. The MEMS device of claim 4, wherein the moving range is associated with an amount of phase shift of the optical beam.

6. The MEMS device of claim 1, further comprising:
an electrode layer disposed under the mirror layer.

7. The MEMS device of claim 6, further comprising:
a substrate layer disposed under the electrode layer.

8. The MEMS device of claim 6, further comprising:
a silicon dioxide layer disposed under the electrode layer.

9. A method for manufacturing a micro-electromechanical system (MEMS) device, comprising:
disposing, by a manufacturing device, an electrode layer on a first wafer layer;
disposing, by the manufacturing device, a mirror layer on a second wafer layer;
bonding, by the manufacturing device, the mirror layer and the electrode layer;
etching, by the manufacturing device, the mirror layer to form an offset between a first surface of the mirror layer and a second surface of the mirror layer; and
etching, by the manufacturing device, the mirror layer to form a set of rotors and a set of stators,
wherein the set of rotors include at least a portion of the first surface of the mirror layer and the set of stators include at least a portion of the second surface of the mirror layer.

10. The method of claim 9, further comprising:
etching the electrode layer to form a stator bonding surface for the set of stators.

11. The method of claim 9, further comprising:
removing a mirror substrate from the mirror layer.

12. The method of claim 9, further comprising:
applying a set of masks to the mirror layer in association with one or more etches the mirror layer.

13. The method of claim 9, further comprising:
forming a hinge to suspend the set of rotor teeth above the electrode layer.

14. The method of claim 9, further comprising:
bonding the set of stator teeth to the electrode layer.

15. A phase-shifting optical device, comprising:
a micro-electromechanical system (MEMS) device, comprising:
a substrate;
an electrode layer disposed on the substrate;
a mirror layer disposed on the electrode layer,
wherein the mirror layer is configured to cause a phase shift of an optical beam;
a set of stator teeth formed from at least a first portion of the mirror layer and at least a portion of the electrode layer; and
a set of rotor teeth formed from at least a second portion of the mirror layer and disposed on a hinge and engaged with the set of stator teeth.

16. The phase-shifting optical device of claim 15, wherein a translational offset between the set of stator teeth and the set of rotor teeth is greater than or equal to a movement range associated with the phase shift and is less than or equal to a threshold amount.

17. The phase-shifting optical device of claim 15, wherein a translational offset between the set of stator teeth and the set of rotor teeth is formed by a shallow etch.

18. The phase-shifting optical device of claim 15, wherein a fixed gap between the set of stator teeth and the set of rotor teeth is less than or equal to a threshold amount.

19. The phase-shifting optical device of claim 15, wherein a stiffness factor of the set of stator teeth and the set of rotor teeth is greater than a threshold amount.

20. The phase-shifting optical device of claim 15, further comprising:
an input to receive an input optical beam; and
an output to output an output optical beam, wherein the output optical beam is phase-shifted, relative to the input optical beam, by an amount associated with a position of the set of rotor teeth relative to the set of stator teeth.
